(19) United States
(12) Patent Application Publication
(10) Pub. No.: US 2017/0031473 A1
(43) Pub. Date: Feb. 2, 2017

(54) TOUCH PANEL MEMBER AND PROCESS FOR PRODUCING SAME, TOUCH PANEL, AND TOUCH PANEL DISPLAY DEVICE

(71) Applicant: FUJIFILM Corporation, Tokyo (JP)

(72) Inventors: Yuzo FUJIKI, Shizuoka (JP); Takeshi ANDO, Shizuoka (JP)

(73) Assignee: FUJIFILM Corporation, Tokyo (JP)

(21) Appl. No.: 15/142,177

(22) Filed: Apr. 29, 2016

(30) Foreign Application Priority Data
Jul. 31, 2015 (JP) 2015-151469

(51) Int. Cl. G06F 3/041; H01L 27/32

(52) U.S. Cl. CPC G06F 3/041; H01L 27/323; G06F 2203/04103

(57) ABSTRACT

It is an object of the present invention to provide a touch panel member that is excellent in terms of suppression of visibility of metal wiring and has little reduction in line width of metal wiring when produced, a touch panel and touch panel display device comprising the touch panel member, and a process for producing the touch panel member.

A touch panel member comprises a support, metal wiring above at least one face of the support, and a layer comprising a metal-organic framework on at least part of the surface of the metal wiring, wherein the layer comprising the metal-organic framework has an average thickness of 10 to 5,000 nm.

### CROSS-REFERENCE TO RELATED APPLICATION

The present application claims a Paris Convention priority to Japanese Patent Application No. 2015-151469 filed on Jul. 31, 2015. The contents of the basic application are incorporated herein by reference in their entirety.

### TECHNICAL FIELD

The present invention relates to a touch panel member and a process for producing same, a touch panel, and a touch panel display device.

### BACKGROUND ART

Flat panel displays such as liquid crystal display devices and organic electroluminescence (EL) display devices are widely used. Furthermore, in recent years, accompanying the widespread use of smart phones and tablet terminals, capacitance type touch panels have been attracting attention. A sensor substrate of a capacitance type touch panel usually has a structure in which wiring is formed by patterning ITO (Indium Tin Oxide) or a metal (silver, molybdenum, aluminum, etc.) on glass; in addition, an intersection of the wiring has an insulating film, and there is a protective film for protecting the ITO and the metal.

As conventional processes for producing a wiring substrate, those described in JP-A-2013-125797 (JP-A denotes a Japanese unexamined patent application publication) and JP-A-2013-189661 are known.

Furthermore, as a conventional method for forming a conductive coating, one described in JP-A-2006-260885 is known.

### SUMMARY OF THE INVENTION

### Problems to be Solved by the Invention

It is an object of the present invention to provide a touch panel member that is excellent in terms of suppression of visibility of metal wiring and has little reduction in line width of metal wiring when produced, a touch panel and touch panel display device comprising the touch panel member, and a process for producing the touch panel member.

### Means for Solving the Problems

The object of the present invention has been accomplished by means described in <1>, or <11> to <13> below. They are described below together with <2> to <10> and <14> to <17>, which are preferred embodiments.

<1> A touch panel member comprising a support, metal wiring above at least one face of the support, and a layer comprising a metal-organic framework on at least part of the surface of the metal wiring, wherein the layer comprising the metal-organic framework has an average thickness of 10 to 5,000 nm,
<2> the touch panel member according to <1>, wherein the layer comprising the metal-organic framework has an average coverage of 80 to 100% with respect to an upper face and side face of the metal wiring in a touch sensor part,
<3> the touch panel member according to <1> or <2>, wherein the metal wiring has an average thickness of 50 to 3,000 nm,
<4> the touch panel member according to any one of <1> to <3>, wherein the metal wiring has a line width of 1 to 10 μm, and the metal wiring has an interwiring distance of 100 to 10,000 μm,
<5> the touch panel member according to any one of <1> to <4>, wherein the metal-organic framework is a structure comprising a metal ion and a compound comprising at least two coordinating groups that coordinate to the metal ion, and the metal ion is an ion of at least one type of metal selected from the group consisting of copper, zinc, cadmium, silver, cobalt, nickel, iron, ruthenium, aluminum, chromium, molybdenum, manganese, palladium, rhodium, and magnesium,
<6> the touch panel member according to <5>, wherein the compound comprising at least two coordinating groups is a compound selected from the group consisting of a compound that comprises a ring comprising a coordinating nitrogen atom within the ring and that comprises at least two coordinating nitrogen atoms, a compound that comprises one each of a carboxyl group and a ring comprising a coordinating nitrogen atom within the ring, and a compound comprising at least two carboxyl groups,
<7> the touch panel member according to <6>, wherein the ring comprising a coordinating nitrogen atom within the ring is an aromatic ring selected from the group consisting of an imidazole ring, a triazole ring, a pyridine ring, and a pyrimidine ring,
<8> the touch panel member according to any one of <1> to <7>, wherein the metal-organic framework comprises a crystal size adjusting agent,
<9> the touch panel member according to <8>, wherein the crystal size adjusting agent is at least one type of compound selected from the group consisting of polyethyleneimine, polyvinylpyrrolidone, a 1-alkylimidazole, a tetraalkylammonium halide, a monoalkylamine, and an aliphatic carboxylic acid,
<10> the touch panel member according to any one of <1> to <9>, wherein the metal wiring is metal wiring comprising at least one type of metal selected from the group consisting of copper, aluminum, titanium, molybdenum, silver, chromium, nickel, and zinc,
<11> a touch panel comprising the touch panel member according to any one of <1> to <10>,
<12> a touch panel display device comprising the touch panel member according to any one of <1> to <10>,
<13> a process for producing a touch panel member, comprising a step of forming metal wiring above a support, and a step of forming a layer that has an average thickness of 10 to 5,000 nm and comprises a metal-organic framework on the surface of the metal wiring using a composition that comprises a solvent, a compound comprising at least two coordinating groups, and at least one type of compound selected from the group consisting of a metal hydroxide and a metal salt of an inorganic acid or organic acid,
<14> the process for producing a touch panel member according to <13>, wherein the composition comprises metal-organic framework particles, and the metal-organic framework particles have an average particle size of 1 to 1,000 nm,
<15> the process for producing a touch panel member according to <13> or <14>, wherein the compound comprising at least two coordinating groups comprises a compound selected from the group consisting of a compound that comprises a ring comprising a coordinating nitrogen atom within the ring and that comprises at least two coordinating nitrogen atoms, a compound that comprises one each of a carboxyl group and a ring comprising a coordinating nitrogen atom within the ring, and a compound comprising at least two carboxyl groups,
<16> the process for producing a touch panel member according to any one of <13> to <15>, wherein the composition further comprises a crystal size adjusting agent, and
<17> the process for producing a touch panel member according to <16>, wherein the crystal size adjusting agent is at least one type of compound selected from the group consisting of polyethyleneimine, polyvinylpyrrolidone, a 1-alkylimidazole, a tetraalkylammonium halide, a monoalkylamine, and an aliphatic carboxylic acid.

### MODES FOR CARRYING OUT THE INVENTION

The content of the present invention is explained in detail below. The explanation of the constituent features given below is based on representative embodiments of the present invention, but the present invention should not be construed as being limited to such embodiments. In the present specification, ‘to’ is used to mean that the numerical values given before and after it are included as a lower limit value and an upper limit value. Furthermore, an organic EL device in the present invention means an organic electroluminescence device.

With regard to the notation of a group (atomic group) in the present specification, a notation that does not indicate whether it is substituted or unsubstituted includes one without a substituent as well as one with a substituent. For example, an ‘alkyl group’ includes an alkyl group without a substituent (unsubstituted alkyl group) as well as an alkyl group with a substituent (substituted alkyl group).

Furthermore, a chemical structural formula in the present specification might be given using a simplified structural formula in which hydrogen atoms are omitted.

In addition, in the present specification, “(meth)acrylate” denotes acrylate and methacrylate, “(meth)acrylic” denotes acrylic and methacrylic, and “(meth)acryloyl” denotes acryloyl and methacryloyl.

Furthermore, in the present invention, ‘mass %’ and ‘wt %’ have the same meaning, and ‘parts by mass’ and ‘parts by weight’ have the same meaning.

Moreover, in the present invention, a combination of two or more preferred embodiments is a more preferred embodiment.

The weight-average molecular weight and number-average molecular weight of a resin in the present invention are measured using a gel permeation chromatography (GPC) method.

### (Touch Panel Member)

The touch panel member of the present invention comprises a support, metal wiring above at least one face of the support, and a layer (hereinafter, also called a ‘MOF layer’) comprising a metal-organic framework (Metal-organic framework, MOF) on at least part of the surface of the metal wiring, wherein the layer comprising the metal-organic framework has an average thickness of 10 to 5,000 nm.

The ‘metal-organic framework’ referred to in the present invention is a crystalline structure having a polymer structure formed by combining metal ions and a crosslinkable organic ligand that joins the metal ions.

The metal wiring and the layer comprising the metal-organic framework may be provided on only one face of the support or may be provided on both faces of the support.

Furthermore, the touch panel member of the present invention may be either a capacitance type or a resistive membrane type, but is preferably a touch panel member for a capacitance type touch panel.

Preferred examples of the capacitance type touch panel include a surface capacitance system and a projected capacitance system.

### <Layer Comprising Metal-Organic Framework>

The touch panel member of the present invention comprises a support, metal wiring above at least one face of the support, and a layer comprising a metal-organic framework on at least part of the surface of the metal wiring, the layer comprising the metal-organic framework having an average thickness of 10 to 5,000 nm.

The layer comprising the metal-organic framework may at least comprise the metal-organic framework, but is preferably a layer comprising the metal-organic framework at 80 mass % or greater, more preferably a layer comprising the metal-organic framework at 90 mass % or greater, and particularly preferably a layer formed from the metal-organic framework.

The average thickness of the layer comprising the metal-organic framework is 10 to 5,000 nm, preferably 20 to 5,000 nm, more preferably 100 to 5,000 nm, and particularly preferably 100 to 1,000 nm. In addition, the average thickness of the layer comprising the metal-organic framework in the present invention is the average value of layer thicknesses measured for at least five positions.

Furthermore, the layer comprising the metal-organic framework may be provided on at least part of the surface of the metal wiring, but the average coverage of the layer comprising the metal-organic framework with respect to an upper face and a side face of the metal wiring in the touch sensor part is preferably 80% to 100%, more preferably 90% to 100%, and particularly preferably 100%.

In addition, the lower face of the metal wiring is a face on the support side, the upper face is a face on the side opposite thereto, and the side face is a face other than the upper face and the lower face.

The touch panel member of the present invention preferably comprises a touch sensor part in which metal wiring for a touch sensor in a touch panel is formed, and may comprise for example a lead-out wiring part, etc. in which metal wiring for lead-out wiring is formed.

Furthermore, the touch panel member of the present invention preferably comprises the layer comprising the metal-organic framework on at least part of the surface of the metal wiring in the touch sensor part. With this embodiment, the effects of the present invention can be further exhibited.

The layer comprising the metal-organic framework is preferably a layer formed by adhering a single layer and/or multiple layers of the metal-organic framework particles to the surface of metal wiring. Furthermore, the metal-organic framework particles are preferably crystalline particles of the metal-organic framework.

The average particle size of the metal-organic framework particles is preferably 1 to 1,000 nm, more preferably 2 to 500 nm, and yet more preferably 3 to 100 nm.

The metal-organic framework is preferably a structure comprising a metal ion and a compound comprising at least two coordinating groups that coordinate to the metal ion.

In order to ascertain the crystallinity of the metal-organic framework, an interference pattern (electron beam diffraction pattern) may be examined by applying an electron beam to a sample taken out of the metal-organic framework.

Examples of the metal ion forming the metal-organic framework include metal ions of transition metals and typical metals; metal ions of transition metals and typical metals of Groups 2, 13, and 14 are preferable, an ion of at least one type of metal selected from the group consisting of copper, zinc, cadmium, silver, cobalt, nickel, iron, ruthenium, aluminum, chromium, molybdenum, manganese, palladium, rhodium, zirconium, titanium, and magnesium is more preferable, an ion of at least one type of metal selected from the group consisting of copper, zinc, silver, cobalt, nickel, iron, and aluminum is yet more preferable, and a copper ion or a zinc ion is particularly preferable. With this embodiment, suppression of visibility of metal wiring is superior, and reduction in the line width of metal wiring during production can be suppressed.

Furthermore, the valency of the metal ion is not particularly limited, but it is preferably mono- to hexa-valent, and more preferably mono- to tri-valent.

The metal of metal wiring in the touch panel member of the present invention may be the same type of metal as the metal ion of the metal-organic framework or a different type of metal.

The organic ligand forming the metal-organic framework may comprise at least a crosslinkable organic ligand.

A compound forming the organic ligand forming the metal-organic framework preferably comprises a compound comprising at least two coordinating groups, more preferably a compound selected from the group consisting of a compound that comprises a ring comprising a coordinating nitrogen atom within the ring and that comprises at least two coordinating nitrogen atoms, a compound that comprises one each of a carboxyl group and a ring comprising a coordinating nitrogen atom within the ring, and a compound that comprises at least two carboxyl groups, and particularly preferably a compound selected from the group consisting of a compound that comprises a ring comprising a coordinating nitrogen atom within the ring and that comprises at least two coordinating nitrogen atoms and a compound that comprises at least two carboxyl groups.

In the metal-organic framework, a compound that comprises a carboxyl group coordinates to a metal ion in the ‘deprotonated’ form —COO⁻.

Furthermore, in the metal-organic framework, the compound that comprises a coordinating nitrogen atom coordinates, in a neutral state, to a metal cation.

The coordinating group of the organic ligand is not particularly limited as long as it can coordinate to a metal ion, but is preferably a coordinating nitrogen atom within an aliphatic ring, a coordinating nitrogen atom within an aromatic ring, a carboxyl anion, or a carboxyl group, more preferably a coordinating nitrogen atom within an aromatic ring, a carboxyl anion, or a carboxyl group, and particularly preferably a coordinating nitrogen atom within an aromatic ring or a carboxyl anion.

The ring comprising a coordinating nitrogen atom within the ring is preferably an aromatic heterocycle comprising a coordinating nitrogen atom within the ring, more preferably an imidazole ring, a triazine ring, a pyridine ring, and/or a pyrimidine ring, and particularly preferably an imidazole ring.

The compound that comprises the ring comprising a coordinating nitrogen atom within the ring and that comprises at least two coordinating nitrogen atoms is preferably a compound comprising an imidazole ring, a triazine ring, and/or a pyrimidine ring, and more preferably a compound comprising an imidazole ring.

Specific preferred examples of the compound that comprises the ring comprising a coordinating nitrogen atom within the ring and that comprises at least two coordinating nitrogen atoms include benzimidazole, 2-methylimidazole, mercaptobenzimidazole, triazine, pyrimidine, 1,4-diazabicyclo[2.2.2]octane (DABCO), and 4,4′-bipyridine; benzimidazole and 2-methylimidazole are more preferable, and benzimidazole is particularly preferable.

Preferred examples of the compound that comprises one each of a carboxyl group and an aromatic ring comprising at least one coordinating nitrogen atom within the ring include a compound comprising a pyridine ring and a carboxyl group.

Specific preferred examples of the compound that comprises one each of a carboxyl group and an aromatic ring comprising at least one coordinating nitrogen atom within the ring include pyridine-3-carboxylic acid (nicotinic acid), pyridine-4-carboxylic acid (isonicotinic acid), 2,2′-bipyridine-4,4′-dicarboxylic acid, 2,2′-bipyridine-6,6′-dicarboxylic acid, 1H-imidazole-4,5-dicarboxylic acid, pyridine-2-carboxylic acid (picolinic acid), 2,3-pyrazinedicarboxylic acid, 2,5-pyridinedicarboxylic acid, and 2,6-pyridinedicarboxylic acid; pyridine-4-carboxylic acid, 1H-imidazole-4,5-dicarboxylic acid, 2,3-pyrazinedicarboxylic acid, 2,5-pyridinedicarboxylic acid, and 2,6-pyridinedicarboxylic acid are more preferable, and pyridine-4-carboxylic acid and 2,3-pyrazinedicarboxylic acid are particularly preferable.

Preferred examples of the compound comprising at least two carboxyl groups include a compound comprising two or more carboxyl groups on an aliphatic ring or an aromatic ring; a compound having two or more carboxyl groups on an aromatic ring is more preferable.

Specific preferred examples of the compound comprising two or more carboxyl groups include trimesic acid (1,3,5-benzenetricarboxylic acid), cis-1,2-cyclohexanedicarboxylic acid, 1,4-benzenedicarboxylic acid, 1,3-benzenedicarboxylic acid, 2,5-diamino-1,4-benzenedicarboxylic acid, and 1,4-cyclohexanedicarboxylic acid; trimesic acid and cis-1,2-cyclohexanedicarboxylic acid are more preferable, and trimesic acid is particularly preferable.

With regard to the compound comprising at least two coordinating groups forming the metal-organic framework, one type may be used on its own or two or more types may be used in combination, but it is preferable to use one type on its own.

Furthermore, as the compound comprising a metal ion and at least two coordinating groups forming the metal-organic framework, for example, those described in Chem. Rev., 2012, 112, 933-969, Science, Vol. 319, 939-943 (2008) and Angew. Chem. Int. Ed., 2004, 43, 2334-2375 may be used.

The content of the organic ligand formed by the compound comprising at least two coordinating groups in the metal-organic framework is preferably 1 to 6 moles per mole of metal, more preferably 1 to 5 moles, yet more preferably 1.1 to 4 moles, and particularly preferably 1.1 to 3 moles.

The metal-organic framework may comprise two or more types of crosslinkable organic ligands and may comprise an organic compound other than a crosslinkable organic ligand (hereinafter, also called ‘another organic compound’).

The metal-organic framework preferably comprises as the other organic compound a crystal size adjusting agent.

The crystal size adjusting agent is preferably at least one type of compound selected from the group consisting of polyethyleneimine, polyvinylpyrrolidone, a 1-alkylimidazole, a tetraalkylammonium halide, a monoalkylamine, and an aliphatic carboxylic acid, more preferably at least one type of compound selected from the group consisting of polyethyleneimine, polyvinylpyrrolidone, 1-methylimidazole, cetyltrimethylammonium bromide, n-butylamine, and dodecanoic acid, and yet more preferably at least one type of compound selected from the group consisting of polyethyleneimine and 1-methylimidazole. With this embodiment, the crystal size of the MOF that is formed becomes uniform, the covering performance for metal wiring is excellent, and suppression of visibility of metal wiring is superior.

The tetraalkylammonium halide, the monoalkylamine, and the aliphatic carboxylic acid preferably comprise at least one alkyl group having 4 to 24 carbons, and more preferably comprise at least one straight-chain alkyl group having 4 to 24 carbons.

Furthermore, the weight-average molecular weight (Mw) of the polyethyleneimine and the polyvinylpyrrolidone is not particularly limited, but is preferably 10,000 to 500,000, and more preferably 20,000 to 400,000.

With regard to the crystal size adjusting agent forming the metal-organic framework, one type may be used on its own or two or more types may be used in combination, but it is preferable to use one type on its own.

The content of the crystal size adjusting agent in the metal-organic framework is preferably 0.1 to 100 parts by mass relative to 100 parts by mass of the total crosslinkable organic ligand content in the metal-organic framework, more preferably 1 to 80 parts by mass, yet more preferably 5 to 60 parts by mass, and most preferably 20 to 60 parts by mass.

A method for forming the layer comprising the metal-organic framework on at least part of the surface of the metal wiring is not particularly limited, but it is preferable for it to be formed by a method described in a process for producing the touch panel member of the present invention, which is described later.

### <Support>

The touch panel member of the present invention comprises a support.

The support that can be used in the present invention is not particularly limited, but is preferably a transparent support. As the transparent support, a known transparent support may be used. For example, glass, quartz, various types of organic film, etc. can be cited.

As a material for the organic film, a resin and a resin composite material can be cited.

Examples of the resin include polybutylene terephthalate, polyethylene terephthalate, polyethylene naphthalate, polybutylene naphthalate, polystyrene, polycarbonate, polysulfone, polyethersulfone, polyallylate, allyldiglycolcarbonate, polyamide, polyimide, polyamide-imide, polyetherimide, polybenzoxazole, polybenzazole, polyphenylene sulfide, a polycycloolefin, a norbornene resin, a fluorine resin such as polychlorotrifluoroethylene, a liquid crystal polymer, an acrylic resin, an epoxy resin, a silicone resin, an ionomer resin, a cyanate resin, a crosslinked fumaric acid diester resin, a cyclic polyolefin, an aromatic ether resin, a maleimide-olefin resin, cellulose, and an episulfide resin.

From the viewpoint of dimensional accuracy and transparency the support is preferably a glass substrate, and from the viewpoint of light weight, resistance to cracking, and flexibility it is preferably an organic film substrate. An organic film may desirably be applied to a so-called roll-to-roll production process.

Among them, a polyester film or a glass substrate is preferable, and a polyethylene terephthalate (PET) film or a glass substrate is more preferable.

The thickness of the support is not particularly limited but is preferably 0.5 μm to 2 mm.

### <Metal Wiring>

The touch panel member of the present invention comprises a support, and metal wiring above at least one face of the support.

The shape of the metal wiring in the touch panel member of the present invention is not particularly limited and may be a desired shape.

In the touch panel member of the present invention, the metal wiring and the support may or may not be in direct contact.

A metal that can be used for the metal wiring is preferably a metal having high conductivity. Examples include copper, aluminum, titanium, molybdenum, silver, chromium, manganese, iron, nickel, zinc, tungsten, palladium, platinum, and gold, and an alloy thereof may be used.

Among them, from the viewpoint of conductivity and ease of patterning, the metal wiring preferably comprises at least one type of metal selected from the group consisting of copper, aluminum, titanium, molybdenum, silver, chromium, nickel, and zinc, more preferably comprises at least one type of metal selected from the group consisting of copper, aluminum, titanium, molybdenum, and silver, and particularly preferably comprises copper. In the present invention, for example, a copper alloy is an alloy comprising copper as a main component. A metal other than the main component in the alloy is not particularly limited, but is preferably a metal cited above.

The metal wiring in the touch panel member of the present invention may comprise a mode in which the metal is dispersed as metal particles in an organic material or may be supported on an organic material. From the viewpoint of conductivity, the mass fraction of the organic material in the metal wiring is preferably no greater than 20 mass % and more preferably no greater than 5 mass %; it is most preferable that no organic material is contained.

The metal wiring in the touch panel member of the present invention is preferably metal wiring in a portion that functions as a touch sensor by detecting the approach, contact, pressing, etc. of a finger, a pen, etc. by means of a change in current, change in capacitance, etc.

The wiring shape (wiring pattern) of the metal wiring is not particularly limited, and examples include a stripe shape and a grid shape (a mesh shape). It is not always necessary for it to be linear, and it may be a wavy shape or a bent line shape.

Furthermore, it is preferable that wiring sections of the metal wiring are insulated from each other. For example, when wiring is superimposed on wiring above a support, it is more preferable for an insulating layer to be present between the sections of wiring.

From the viewpoint of conductivity and prevention of pattern defects, the average thickness of the metal wiring is preferably 20 to 5,000 nm, more preferably 50 to 3,000 nm, and yet more preferably 80 to 2,000 nm. The average thickness of the metal wiring in the present invention is the average value of thicknesses measured at five or more positions.

The line width of the metal wiring is preferably 1 to 20 μm, more preferably 1 to 10 μm, yet more preferably 1 to 8 μm, and particularly preferably 1 to 7 μm. When in this range, suppression of visibility is superior.

The interwiring distance of the metal wiring is not particularly limited and may be set as desired, but from the viewpoint of suppression of visibility it is preferably 25 to 10,000 μm, more preferably 50 to 5,000 μm, and yet more preferably 100 to 3,000 μm.

Furthermore, from the viewpoint of prevention of pattern defects and visibility, the value for said average thickness of metal wiring/line width of metal wiring is preferably 0.005 to 10, more preferably 0.01 to 1, and yet more preferably 0.02 to 0.5.

A method for forming the metal wiring is not particularly limited, and a known method may be used; it is preferable for it to be formed by for example a method described for the process for producing a touch panel member of the present invention, which is described later.

The touch panel member of the present invention may comprise a known layer other than the support, the metal wiring, and the layer comprising the metal-organic framework. Examples include a protective layer, an insulating layer, an adhesion layer, and a pressure-sensitive adhesion layer.

The material for each layer of the protective layer, the insulating layer, the adhesion layer, and the pressure-sensitive adhesion layer is not particularly limited, and a known material may be used.

### (Process for Producing Touch Panel Member)

The process for producing a touch panel member of the present invention comprises a step of forming metal wiring above a support (also called a ‘wiring formation step’), and a step of forming a layer that has an average thickness of 10 to 5,000 nm and comprises a metal-organic framework on the surface of the metal wiring using a composition that comprises a solvent, a compound comprising at least two coordinating groups, and at least one type of compound selected from the group consisting of a metal hydroxide and a metal salt of an inorganic acid or organic acid (also called an ‘MOF layer formation step’).

The touch panel member of the present invention is preferably one produced by the process for producing a touch panel member of the present invention.

### <Wiring Formation Step>

The process for producing a touch panel member of the present invention comprises a step of forming metal wiring above a support (wiring formation step).

In the wiring formation step, the metal wiring and the support may or may not be in direct contact.

The support and metal wiring in the wiring formation step are not particularly limited; the support and metal wiring in the touch panel member of the present invention described above may be cited, and preferred embodiments thereof are also the same.

A method for forming metal wiring in the wiring formation step is not particularly limited; a known method may be used, and examples include a screen printing, gravure offset printing, or inkjet printing method in which a metal paste is provided along a wiring pattern by coating, a method in which plating is carried out along a wiring pattern shape, and a method in which metal wiring is formed by etching a metal film. In particular, from the viewpoint of fine line formation, a method in which metal wiring is formed by etching a metal film can be cited as a preferred example.

A method for etching a metal film is not particularly limited; a known etching method may be used, and for example wet etching or dry etching may be employed, but from the viewpoint of cost it is preferable to employ wet etching.

Furthermore, etching conditions are not particularly limited either, and etching may be carried out using any temperature, time, and atmosphere.

An etching liquid used for wet etching is not particularly limited; a known etching liquid may be used, and it may be selected as appropriate according to the material of the metal film used and the material of a resist.

An etching liquid composition described in JP-A-2013-89731 or JP-A-2011-228618 can be cited as a preferred example. Specific examples include an iron chloride aqueous solution, a hydrogen peroxide aqueous solution, nitric acid, phosphoric acid, acetic acid, hydrofluoric acid, and a mixed liquid thereof.

Furthermore, a known resist may be used in etching.

A method for forming a resist pattern is not particularly limited, but a preferred example includes a method in which an etching resist pattern for etching is formed using a so-called photolithographic method in which a resist layer is exposed in a desired pattern shape.

The photolithographic method is not particularly limited; known exposure means or a known mask, and a known developer may be used. Furthermore, after development, a known rinsing step or washing step may be carried out.

Moreover, the resist may be a positive-working resist or a negative-working resist; from the viewpoint of fine line formation, a positive-working resist is preferable, and it is more preferably a chemically amplified positive-working resist.

As an exposure light source, a low-pressure mercury lamp, a high pressure mercury lamp, an ultra high-pressure mercury lamp, a chemical lamp, an LED light source, an excimer laser generator, etc. may be used, and actinic radiation having a wavelength of at least 300 nm but no greater than 450 nm such as g-line (436 nm), i-line (365 nm), or h-line (405 nm) may preferably be used. The irradiating light may be adjusted as necessary by way of a spectral filter such as a long wavelength cut filter, a short wavelength cut filter, or a band-pass filter.

As exposure equipment, various types of exposure system such as a mirror projection aligner, a stepper, a scanner, proximity, contact, a microlens array, and laser exposure may be used.

Furthermore, examples of actinic radiation used in exposure include a rays, γ rays, X rays, UV, visible light, and an electron beam. Among them, from the viewpoint of sensitivity and ready availability of equipment, visible light and UV are preferable, and UV is more preferable.

### <MOF Layer Formation Step>

The process for producing a touch panel member of the present invention includes a step (MOF layer formation step) of forming a layer that has an average thickness of 10 to 5,000 nm and comprises a metal-organic framework on the surface of the metal wiring using a composition that comprises a solvent, a compound comprising at least two coordinating groups, and at least one type of compound selected from the group consisting of a metal hydroxide and a metal salt of an inorganic acid or organic acid.

In the MOF layer formation step, it is preferable that a composition comprising a solvent, a compound comprising at least two coordinating groups, and at least one type of compound selected from the group consisting of a metal hydroxide and a metal salt of an inorganic acid or an organic acid is contacted with the metal wiring to thus form a layer comprising a metal-organic framework, and it is more preferable that a support having the metal wiring is immersed in a composition comprising a solvent, a compound comprising at least two coordinating groups, and at least one type of compound selected from the group consisting of a metal hydroxide and a metal salt of an inorganic acid or an organic acid to thus form a layer comprising a metal-organic framework.

The temperature of the composition at the time of formation of a layer comprising a metal-organic framework is not particularly limited, but there is a tendency for it to be easier to form MOF crystals the higher the temperature of the composition is. From the viewpoint of appropriately adjusting the speed and size of crystallization and improving wiring coverage, the temperature of the composition is preferably 0° C. to 80° C., and more preferably 10° C. to 60° C.

Furthermore, the time during which the composition is contacted with the metal wiring is not particularly limited; it may be adjusted as appropriate according to the desired thickness of the layer comprising a metal-organic framework, the formulation of the composition, etc., and it is preferably 1 minute to 24 hours, and more preferably 10 minutes to 6 hours.

As the compound comprising at least two coordinating groups used in the MOF layer formation step, the compound comprising at least two coordinating groups described above for the touch panel member of the present invention can be cited as an example, and preferred embodiments are also the same.

As the metal of the metal salt of an inorganic acid or an organic acid used in the MOF layer formation step, the metal of the metal ion forming the metal-organic framework described above for the touch panel member of the present invention can be cited as an example, and preferred embodiments are also the same.

As the metal salt of an inorganic acid or an organic acid, a metal salt of an inorganic acid is preferable. The metal salt may be a hydrate.

Preferred examples of the inorganic acid include nitric acid, sulfuric acid, an iodide such as hydroiodic acid or an oxoacid of iodine, a bromide such as hydrobromic acid or an oxoacid of bromine, and hydrochloric acid; nitric acid, hydroiodic acid, hydrobromic acid, or sulfuric acid is more preferable, and nitric acid is particularly preferable.

Preferred examples of the organic acid include an alkyl- or aryl-sulfonic acid and citric acid.

The metal hydroxide is preferably a metal hydroxide comprising a metal ion forming the metal-organic framework in the touch panel member of the present invention described above, and more preferably copper hydroxide.

The solvent is preferably water, a polar organic solvent, or a mixed solvent of water and a polar organic solvent, and more preferably a mixed solvent of water and a polar organic solvent. With this embodiment, the layer comprising a metal-organic framework may be easily formed.

Examples of the polar organic solvent include an alcohol such as methanol, ethanol, or butanol, a sulfoxide such as dimethylsulfoxide, an amide such as N,N-dimethylformamide, N-methylformamide, N,N-dimethylacetamide, N-methylacetamide, or N,N-diethylacetamide; and a lactam such as N-methyl-2-pyrrolidone, N-ethyl-2-pyrrolidone, or N-propyl-2-pyrrolidone.

Among them, an alcohol or an amide is preferable, and methanol, ethanol, or N,N-dimethylformamide is more preferable.

The content of the solvent in the composition is preferably at least 95 mass % with respect to the total mass of the composition, more preferably at least 99 mass %, yet more preferably at least 99.5 mass %, and particularly preferably at least 99.8 mass %. With this range, precipitation of the metal-organic framework can be suppressed.

The content of the metal salt of the inorganic acid or organic acid in the composition is preferably 0.005 to 1 mass % with respect to the total mass of the composition, more preferably 0.01 to 0.5 mass %, and yet more preferably 0.02 to 0.2 mass %. With this range, ease of formation of the metal-organic framework is excellent.

The content of the compound comprising at least two coordinating groups in the composition is preferably 1 to 6 moles per mole of metal ion in the metal salt of the inorganic acid or organic acid, more preferably 1 to 5 moles, yet more preferably 1.1 to 4 moles, and particularly preferably 1.1 to 3 moles.

Furthermore, the composition preferably comprises metal-organic framework particles. The metal-organic framework particles are preferably crystalline particles of the metal-organic framework.

The average particle size of the metal-organic framework particles in the composition is preferably 1 to 1,000 nm, more preferably 2 to 500 nm, and yet more preferably 3 to 100 nm.

Moreover, the composition may comprises an organic compound other than said solvent, compound comprising at least two coordinating groups, and at least one type of compound selected from the group consisting of a metal hydroxide and a metal salt of an inorganic acid or an organic acid.

The composition preferably comprises a crystal size adjusting agent as the other organic compound.

Examples of the crystal size adjusting agent include the crystal size adjusting agent described above for the touch panel member of the present invention, and preferred embodiments are also the same.

The content of the crystal size adjusting agent in the composition is preferably 0.1 to 100 parts by mass relative to 100 parts by mass of the total content of the compound comprising at least two coordinating groups, more preferably 1 to 80 parts by mass, yet more preferably 5 to 60 parts by mass, and most preferably 20 to 60 parts by mass.

The process for producing a touch panel member of the present invention preferably comprises a step (washing step) of washing a support comprising metal wiring and a layer comprising a metal-organic framework after the MOF layer formation step.

A washing liquid used in the washing step is preferably an alcohol, water, or a mixed liquid thereof, and more preferably a pure water such as deionized water or distilled water.

The process for producing a touch panel member of the present invention may comprise a known step other than the steps above.

Examples thereof include a step of forming a protective layer, an insulating layer, an adhesive layer, or a pressure-sensitive adhesion layer.

### (Touch Panel and Touch Panel Display Device)

The touch panel of the present invention comprises the touch panel member of the present invention.

The touch panel display device of the present invention comprises the touch panel member of the present invention.

As a detection method, various known types of methods such as a capacitance method, a resistive film method, or an optical method may be employed. Among them, a capacitance method is preferable.

As a touch panel type, the so-called in-cell type (for example, those shown in FIG. 5, FIG. 6, FIG. 7, and FIG. 8 of published Japanese translation 2012-517051 of a PCT application), the so-called on-cell type (for example, one shown in FIG. 19 of JP-A-2013-168125, those shown in FIG. 1 and FIG. 5 of JP-A-2012-89102), an OGS (One Glass Solution) type, a TOL (Touch-on-Lens) type (for example, one shown in FIG. 2 of JP-A-2013-54727), another constitution (for example, one shown in FIG. 6 of JP-A-2013-164871), and various kinds of out-cell type (so-called GG, G1·G2, GFF, GF2, GF1, G1F, etc.) can be cited.

The touch panel and the touch panel device of the present invention is preferably an on-cell type, an OGS type, a TOL type, another constitution, or various kinds of out-cell type in terms of the effect in improving framework visibility and improving taper visibility being easily exhibited.

The touch panel of the present invention and the touch panel display device equipped with the touch panel of the present invention as a constituent element may employ a constitution disclosed in “Saishin Tacchipaneru Gijutsu” (Latest Touch Panel Technology) (published on 6 Jul. 2009, Technotimes), “Tacchipaneru-no-gijutsu-to-kaihatsu” (Touch Panel Technology and Development), CMC Publishing Co., Ltd. (edited by Yuji Mitani, 2004, 12), FPD International 2009 Forum T-11 Lecture Textbook, Cypress Semiconductor Corporation Application Note AN2292, etc.

In accordance with the present invention, there can be provided a touch panel member that is excellent in terms of suppression of visibility of metal wiring and has little reduction in line width of metal wiring when produced, a touch panel and touch panel display device comprising the touch panel member, and a process for producing the touch panel member.

### EXAMPLES

The present invention is further specifically explained by reference to the following Examples. The materials, amount of material used, proportions, processing details, processing procedure, etc. shown in the Examples below may be modified as appropriate as long as the modifications do not depart from the spirit and scope of the present invention. Therefore, the scope of the present invention should not be construed as being limited to the specific Examples shown below. In addition, ‘parts’ and ‘%’ are on a mass basis unless otherwise specified.

### Example 1

### (1) Resist Layer Formation Step

A substrate in which a 200 nm thick copper film was formed on a glass substrate (100 mm×100 mm) was coated by spin coating with a resist composition having the formulation below and dried.

### <Resist Composition>

A resist composition was obtained by mixing and dissolving each of the components below and filtering using a polytetrafluoroethylene filter having a pore size of 0.2 μm.

PHS-EVE (p-hydroxystyrene 1-ethoxyethyl-protected derivative/p-hydroxystyrene copolymer (30 mole %/70 mole %), structure below): 71.4 parts
Acrylic polymer below: 28.6 parts
IRGACURE PAG103 (BASF): 2.7 parts
Dibutoxyanthracene: 2.7 parts
Epoxy resin (JER157S65, Japan Epoxy Resins Co., Ltd.): 2.7 parts
Solvent PGMEA (propylene glycol monomethyl ether acetate): adjustment carried out so that the non-volatile content was 10 mass % of the entire

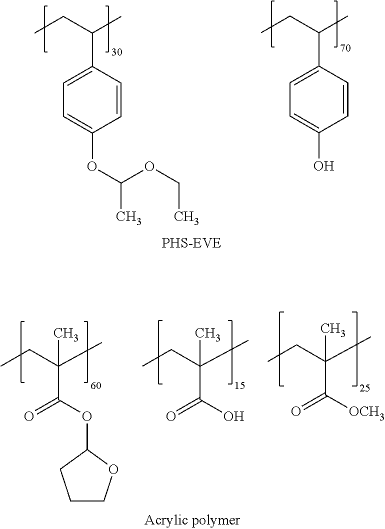

The numerals on the bottom right of the parentheses of the respective constituent units of the acrylic polymer (Acrylic polymer) denote molar ratio.

### (2) Resist Pattern Formation Step

The substrate having formed thereon the photosensitive composition layer (resist layer) produced in the resist layer formation step was exposed to a pattern having a line width of 5 μm and a wiring pitch of 1:600 using an MPA 5500CF (high-pressure mercury lamp) manufactured by Canon.

After the exposed photosensitive resin composition layer was developed using an alkali developer (2.38% tetramethylammonium hydroxide aqueous solution), it was rinsed with ultrapure water, thus producing a patterned resist layer.

### (3) Metal Pattern Formation Step

The substrate having formed thereon the patterned resist layer was immersed in a copper etchant (CleanEtch SE-07, Ryoko Chemical Co., Ltd., 7 times diluted product) at 30° C. for 1 minute and then rinsed with ultrapure water. By these procedures, the copper was wet-etched, thus forming a copper wiring pattern having a line width of 5 μm, a wiring film thickness of 200 nm, and a wiring pitch of 1:600.

### (4) Resist Removal Step

The patterned copper substrate produced in the metal pattern formation step was immersed in a resist stripping agent (N-300, Nagase ChemteX Corporation) at 40° C. for 2 minutes and then rinsed with ultrapure water. By these procedures, the patterned resist layer was removed.

### (5) MOF Formation Step

An MOF processing solution was prepared by mixing the components below.

Copper nitrate: 0.045 parts (0.19 molar equivalents)
Benzimidazole: 0.045 parts (0.38 molar equivalents)
Dimethylformamide (DMF)/water (mass ratio 1:3): 90 parts

The patterned copper substrate produced in the resist removal step was immersed in the prepared MOF processing solution at 25° C. for 10 minutes.

Subsequently, the substrate was washed well with pure water so as to remove the MOF processing solution, thus giving a touch panel member of Example 1.

### <MOF Evaluation>

### MOF Layer Thickness

A piece of the metal wiring portion having the layer comprising the metal-organic framework formed thereon was produced and subjected to TEM examination. An electron diffraction image of the layer comprising the metal-organic framework and the metal wiring was ascertained. After the layer comprising the metal-organic framework was identified, the layer thickness was measured for five or more positions, thus giving the average thickness of the layer comprising the metal-organic framework.

5: greater than 1,000 nm but no greater than 5,000 nm on average
4: at least 100 nm but no greater than 1,000 nm on average
3: at least 2 nm but less than 100 nm on average
2: greater than 0 nm but less than 2 nm on average
1: no MOF formed

### Coverage

The touch panel member obtained was subjected to SEM examination from the front with respect to a face having the metal wiring and MOF formed thereon. An upper face and a side face of the metal wiring for a given area (5 μm×50 μm=250 μm²) were examined, and the area of a portion where the MOF layer was observed and the area of a portion where it was not observed were determined. With regard to (area of portion where it was observed/250 μm²), five positions were measured and the average value was calculated. The coverage of metal wiring with the MOF was evaluated as follows.

5: 100%
4: at least 90% but less than 100%
3: at least 80% but less than 90%
2: at least 50% but less than 80%
1: less than 50%

### MOF Average Particle Size

With regard to the MOF processing solution obtained, the particle size distribution was determined. When the solution concentration was high, the solution was diluted as necessary with dimethylformamide (DMF)/water (mass ratio 1:3), and subjected to measurement using a particle size profiler (Microtrack, Nikkiso Co., Ltd.).

Evaluation was made as follows with respect to the average particle size of the MOF.

5: greater than 1 nm but no greater than 5 nm
4: greater than 5 nm but no greater than 50 nm
3: greater than 50 nm but less than 1,000 nm
2: precipitation (at least 1,000 nm)
1: not observed (no greater than 1 nm)

### <Touch Panel Member Evaluation>

### Amount of Line Width Reduction

The touch panel member obtained was cut using a FIB (focused ion beam) so as to form a cross-section that was perpendicular to the face where the metal wiring and MOF were formed, and the cross-section was subjected to scanning electronic microscopy (SEM). The line width of the metal wiring was measured for five positions, and the amount of line width reduction of the metal wiring was obtained as an average value. Evaluation was made as follows with respect to the amount of line width reduction.

5: less than 0.5 μm
4: at least 0.5 μm but less than 1.0 μm
3: at least 1.0 μm but less than 1.5 μm
2: at least 1.5 μm
1: metal wiring dissolved and open circuit

### Suppression of Visibility

Evaluation was made on the below basis of the degree of whiteness of the wiring pattern for a touch sensor when the touch panel member obtained was placed on a black desk, which did not reflect light, under a fluorescent lamp (about 500 lux). The lower the whiteness, the better it was, and a value of 3 or greater was in a practical range.

5: no whiteness when viewed from any direction.
4: no whiteness when viewed from the front but slight whiteness when viewed obliquely.
3: slight whiteness when viewed from the front and slight whiteness when viewed obliquely.
2: slight whiteness when viewed from the front, and whiteness could be clearly recognized when viewed obliquely.
1: whiteness could be clearly recognized even when viewed from the front.

### Examples 2 to 53 and Comparative Examples 1 and 2

Touch panel members of Examples and Comparative Examples were produced in the same manner as in Example 1 except that the type of metal, metal film thickness, resist exposure pattern (metal wiring film thickness and wiring pitch), and MOF processing solution were changed as described in Table 1 to Table 3, and evaluation was carried out. The evaluation results are shown together in Table 4 to Table 6.

The etchants (etching liquids) used in Examples 40 to 43 were as follows.

Silver etchant: silver etching liquid SEA-4 (KANTO CHEMICAL CO., INC.)
Aluminum etchant: mixed acid aluminum etching liquid (KANTO CHEMICAL CO., INC.)
TAT etchant: layer film etching liquid KSMF-200 (KANTO CHEMICAL CO., INC.)
MAM etchant: layer film etching liquid KSMF-100 (KANTO CHEMICAL CO., INC.)

The amount of water added in Comparative Example 2 was an amount that made the pH 3.7 when the amount of thioisocyanuric acid given in Table 3 was added.

### Comparative Example 3

A plating bath was prepared by putting in 60 parts of nickel sulfate, 35 parts of ammonium nickel sulfate, 20 parts of zinc sulfate, 18 parts of sodium thiocyanate, and 867 parts of pure water. The pH of the plating processing solution was adjusted to 5.0, and processing was carried out at a processing solution temperature of 50° C. and an electro-plating current density of 1 A/cm². Subsequently, washing with water and then air drying were carried out, thus giving the touch panel member of Comparative Example 3.

### Comparative Example 4

The patterned copper substrate produced in the resist removal step was used and immersed in a blackening treatment bath (aqueous solution formed by dissolving 30 parts of sodium chlorite, 10 parts of trisodium phosphate dodecahydrate, and 15 parts of sodium hydroxide in 945 parts of pure water) at a treatment temperature of 90° C. for 3 minutes. Subsequently, washing with water and then air drying were carried out, thus giving the touch panel member of Comparative Example 4.

TABLE 1

| | | | | | | Metal wiring | | | |
|---|---|---|---|---|---|---|---|---|---|
| | | | | | | | | Wiring | |
| | | | | | | | Line | film | |
| | MOF processing solution | | | | | Metal | width | thickness | Wiring |
| | Metal source | Amount added | Ligand 1 | Amount added | Solvent | type | (μm) | (nm) | pitch |
| Ex. 1 | Cu(NO₃)₂•3H₂O | 0.045 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 2 | Fe(NO₃)₃ | 0.045 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 3 | Co(NO₃)₂•6H₂O | 0.054 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 4 | Ni(NO₃)₂•6H₂O | 0.054 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 5 | Al(NO₃)₃•9H₂O | 0.070 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 6 | Zn(NO₃)₂ | 0.056 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 7 | AgNO₃ | 0.032 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 8 | ZrCl₄ | 0.044 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 9 | CuBr | 0.027 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 10 | CuI | 0.036 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 11 | CuCl₂ | 0.025 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 12 | Cu(OH)₂ | 0.019 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 13 | Cu(C₆H₄O₇)•2.5H₂O | 0.059 parts (0.19 | Benzimidazole | 0.045 parts (0.38 | DMF/water | Cu | 5 | 200 | 1:600 |
| | | molar equivalents) | | molar equivalents) | 90 parts | | | | |
| Ex. 14 | Cu(NO₃)₂•3H₂O | 0.045 parts (0.19 | 2-Methylimidazole | 0.031 parts (0.38 | DMF/water | Cu | 5 | 200 | 1:600 |
| | | molar equivalents) | | molar equivalents) | 90 parts | | | | |
| Ex. 15 | Cu(NO₃)₂•3H₂O | 0.045 parts (0.19 | Mercapto | 0.057 parts (0.38 | DMF/water | Cu | 5 | 200 | 1:600 |
| | | molar equivalents) | benzimidazole | molar equivalents) | 90 parts | | | | |
| Ex. 16 | Cu(NO₃)₂•3H₂O | 0.045 parts (0.19 | Triazine | 0.031 parts (0.38 | DMF/water | Cu | 5 | 200 | 1:600 |
| | | molar equivalents) | | molar equivalents) | 90 parts | | | | |
| Ex. 17 | Cu(NO₃)₂•3H₂O | 0.045 parts (0.19 | DABCO | 0.043 parts (0.38 | DMF/water | Cu | 5 | 200 | 1:600 |
| | | molar equivalents) | | molar equivalents) | 90 parts | | | | |
| Ex. 18 | Cu(NO₃)₂•3H₂O | 0.045 parts (0.19 | 4,4′-Bipyridine | 0.059 parts (0.38 | DMF/water | Cu | 5 | 200 | 1:600 |
| | | molar equivalents) | | molar equivalents) | 90 parts | | | | |
| Ex. 19 | Cu(NO₃)₂•3H₂O | 0.045 parts (0.19 | Pyrimidine | 0.030 parts (0.38 | DMF/water | Cu | 5 | 200 | 1:600 |
| | | molar equivalents) | | molar equivalents) | 90 parts | | | | |
| Ex. 20 | Cu(NO₃)₂•3H₂O | 0.045 parts (0.19 | Pyridine-4- | 0.047 parts (0.38 | DMF/water | Cu | 5 | 200 | 1:600 |
| | | molar equivalents) | carboxylic acid | molar equivalents) | 90 parts | | | | |
| Ex. 21 | Cu(NO₃)₂•3H₂O | 0.045 parts (0.19 | 2,3-Pyrazine | 0.064 parts (0.38 | DMF/water | Cu | 5 | 200 | 1:600 |
| | | molar equivalents) | dicarboxylic acid | molar equivalents) | 90 parts | | | | |
| Ex. 22 | Cu(NO₃)₂•3H₂O | 0.045 parts (0.19 | Trimesic acid | 0.080 parts (0.38 | DMF/water | Cu | 5 | 200 | 1:600 |
| | | molar equivalents) | | molar equivalents) | 90 parts | | | | |
| Ex. 23 | Cu(NO₃)₂•3H₂O | 0.045 parts (0.19 | cis-1,2-Benzene | 0.065 parts (0.38 | DMF/water | Cu | 5 | 200 | 1:600 |
| | | molar equivalents) | dicarboxylic acid | molar equivalents) | 90 parts | | | | |

TABLE 2

| | MOF processing solution | | | | | | | Metal wiring | | | |
|---|---|---|---|---|---|---|---|---|---|---|---|
| | | | | | Ligand 2 | | | | | Wiring | |
| | | | | | (crystal size | | | | Line | film | |
| | | Amount | | Amount | adjusting | Amount | | Metal | width | thickness | Wiring |
| | Metal source | added | Ligand 1 | added | agent) | added | Solvent | type | (μm) | (nm) | pitch |
| Ex. 24 | Cu(NO₃)₂•3H₂O | 0.150 parts | Benzimidazole | 0.118 parts | None | — | DMF/water | Cu | 5 | 200 | 1:600 |
| | | (0.63 molar | | (1.0 molar | | | 90 parts | | | | |
| | | equivalents) | | equivalents) | | | | | | | |
| Ex. 25 | Cu(NO₃)₂•3H₂O | 0.090 parts | Benzimidazole | 0.045 parts | None | — | DMF/water | Cu | 5 | 200 | 1:600 |
| | | (0.38 molar | | (0.38 molar | | | 90 parts | | | | |
| | | equivalents) | | equivalents) | | | | | | | |
| Ex. 26 | Cu(NO₃)₂•3H₂O | 0.045 parts | Benzimidazole | 0.022 parts | None | — | DMF/water | Cu | 5 | 200 | 1:600 |
| | | (0.19 molar | | (0.19 molar | | | 90 parts | | | | |
| | | equivalents) | | equivalents) | | | | | | | |
| Ex. 27 | Cu(NO₃)₂•3H₂O | 0.022 parts | Benzimidazole | 0.022 parts | None | — | DMF/water | Cu | 5 | 200 | 1:600 |
| | | (0.09 molar | | (0.19 molar | | | 90 parts | | | | |
| | | equivalents) | | equivalents) | | | | | | | |
| Ex. 28 | Cu(NO₃)₂•3H₂O | 0.045 parts | Benzimidazole | 0.045 parts | PEI | 0.018 | DMF/water | Cu | 5 | 200 | 1:600 |
| | | (0.19 molar | | (0.38 molar | | parts | 90 parts | | | | |
| | | equivalents) | | equivalents) | | | | | | | |
| Ex. 29 | Cu(NO₃)₂•3H₂O | 0.045 parts | 2-Methyl | 0.031 parts | PEI | 0.018 | DMF/water | Cu | 5 | 200 | 1:600 |
| | | (0.19 molar | imidazole | (0.38 molar | | parts | 90 parts | | | | |
| | | equivalents) | | equivalents) | | | | | | | |
| Ex. 30 | Cu(NO₃)₂•3H₂O | 0.045 parts | Benzimidazole | 0.045 parts | PVP | 0.018 | DMF/water | Cu | 5 | 200 | 1:600 |
| | | (0.19 molar | | (0.38 molar | | parts | 90 parts | | | | |
| | | equivalents) | | equivalents) | | | | | | | |
| Ex. 31 | Cu(NO₃)₂•3H₂O | 0.045 parts | Benzimidazole | 0.045 parts | 1-Methyl | 0.018 | DMF/water | Cu | 5 | 200 | 1:600 |
| | | (0.19 molar | | (0.38 molar | imidazole | parts | 90 parts | | | | |
| | | equivalents) | | equivalents) | | | | | | | |
| Ex. 32 | Zn(NO₃)₂ | 0.055 parts | 2-Methyl | 0.031 parts | 1-Methyl | 0.018 | DMF/water | Cu | 5 | 200 | 1:600 |
| | | (0.19 molar | imidazole | (0.38 molar | imidazole | parts | 90 parts | | | | |
| | | equivalents) | | equivalents) | | | | | | | |
| Ex. 33 | Cu(NO₃)₂•3H₂O | 0.045 parts | Benzimidazole | 0.045 parts | Cetyl | 0.018 | DMF/water | Cu | 5 | 200 | 1:600 |
| | | (0.19 molar | | (0.38 molar | trimethyl | parts | 90 parts | | | | |
| | | equivalents) | | equivalents) | ammonium | | | | | | |
| | | | | | bromide | | | | | | |
| Ex. 34 | Cu(NO₃)₂•3H₂O | 0.045 parts | Benzimidazole | 0.045 parts | n-Butylamine | 0.018 | DMF/water | Cu | 5 | 200 | 1:600 |
| | | (0.19 molar | | (0.38 molar | | parts | 90 parts | | | | |
| | | equivalents) | | equivalents) | | | | | | | |
| Ex. 35 | Cu(NO₃)₂•3H₂O | 0.045 parts | Trimesic acid | 0.080 parts | PEI | 0.018 | DMF/water | Cu | 5 | 200 | 1:600 |
| | | (0.19 molar | | (0.38 molar | | parts | 90 parts | | | | |
| | | equivalents) | | equivalents) | | | | | | | |
| Ex. 36 | Cu(NO₃)₂•3H₂O | 0.045 parts | Trimesic acid | 0.080 parts | Dodecanoic | 0.018 | DMF/water | Cu | 5 | 200 | 1:600 |
| | | (0.19 molar | | (0.38 molar | acid | parts | 90 parts | | | | |
| | | equivalents) | | equivalents) | | | | | | | |
| Ex. 37 | Cu(NO₃)₂•3H₂O | 0.045 parts | Benzimidazole | 0.045 parts | None | — | Methanol/ | Cu | 5 | 200 | 1:600 |
| | | (0.19 molar | | (0.38 molar | | | water | | | | |
| | | equivalents) | | equivalents) | | | 90 parts | | | | |
| Ex. 38 | Zn(NO₃)₂ | 0.055 parts | 2-Methyl | 0.031 parts | None | — | Methanol/ | Cu | 5 | 200 | 1:600 |
| | | (0.19 molar | imidazole | (0.38 molar | | | water | | | | |
| | | equivalents) | | equivalents) | | | 90 parts | | | | |
| Ex. 39 | Cu(NO₃)₂•3H₂O | 0.045 parts | Trimesic acid | 0.080 parts | None | — | Methanol/ | Cu | 5 | 200 | 1:600 |
| | | (0.19 molar | | (0.38 molar | | | water | | | | |
| | | equivalents) | | equivalents) | | | 90 parts | | | | |

TABLE 3

| | | | | | | Metal wiring | | | |
|---|---|---|---|---|---|---|---|---|---|
| | | | | | | | | Wiring | |
| | | | | | | | Line | film | |
| | MOF processing solution | | | | | Metal | width | thickness | Wiring |
| | Metal source | Amount added | Ligand 1 | Amount added | Solvent | type | (μm) | (nm) | pitch |
| Ex. 40 | Cu(NO₃)₂•3H₂O | 0.045 parts (0.19 | Benzimidazole | 0.045 parts (0.38 | DMF/water | Silver | 5 | 200 | 1:600 |
| | | molar equivalents) | | molar equivalents) | 90 parts | | | | |
| Ex. 41 | Cu(NO₃)₂•3H₂O | 0.045 parts (0.19 | Benzimidazole | 0.045 parts (0.38 | DMF/water | Aluminum | 5 | 200 | 1:600 |
| | | molar equivalents) | | molar equivalents) | 90 parts | | | | |
| Ex. 42 | Cu(NO₃)₂•3H₂O | 0.045 parts (0.19 | Benzimidazole | 0.045 parts (0.38 | DMF/water | TAT | 5 | 200 | 1:600 |
| | | molar equivalents) | | molar equivalents) | 90 parts | | | | |
| Ex. 43 | Cu(NO₃)₂•3H₂O | 0.045 parts (0.19 | Benzimidazole | 0.045 parts (0.38 | DMF/water | MAM | 5 | 200 | 1:600 |
| | | molar equivalents) | | molar equivalents) | 90 parts | | | | |
| Ex. 44 | Cu(NO₃)₂•3H₂O | 0.045 parts (0.19 | Benzimidazole | 0.045 parts (0.38 | DMF/water | Cu | 3 | 200 | 1:600 |
| | | molar equivalents) | | molar equivalents) | 90 parts | | | | |
| Ex. 45 | Cu(NO₃)₂•3H₂O | 0.045 parts (0.19 | Benzimidazole | 0.045 parts (0.38 | DMF/water | Cu | 4 | 200 | 1:600 |
| | | molar equivalents) | | molar equivalents) | 90 parts | | | | |
| Ex. 46 | Cu(NO₃)₂•3H₂O | 0.045 parts (0.19 | Benzimidazole | 0.045 parts (0.38 | DM F/water | Cu | 8 | 200 | 1:600 |
| | | molar equivalents) | | molar equivalents) | 90 parts | | | | |
| Ex. 47 | Cu(NO₃)₂•3H₂O | 0.045 parts (0.19 | Benzimidazole | 0.045 parts (0.38 | DMF/water | Cu | 10 | 200 | 1:600 |
| | | molar equivalents) | | molar equivalents) | 90 parts | | | | |
| Ex. 48 | Zn(NO₃)₂ | 0.055 parts (0.19 | 2-Methylimidazole | 0.031 parts (0.38 | DMF/water | Cu | 3 | 200 | 1:600 |
| | | molar equivalents) | | molar equivalents) | 90 parts | | | | |
| Ex. 49 | Cu(NO₃)₂•3H₂O | 0.045 parts (0.19 | Benzimidazole | 0.045 parts (0.38 | DMF/water | Cu | 5 | 200 | 1:300 |
| | | molar equivalents) | | molar equivalents) | 90 parts | | | | |
| Ex. 50 | Zn(NO₃)₂ | 0.055 parts (0.19 | 2-Methylimidazole | 0.031 parts (0.38 | DMF/water | Cu | 5 | 200 | 1:300 |
| | | molar equivalents) | | molar equivalents) | 90 parts | | | | |
| Ex. 51 | Cu(NO₃)₂•3H₂O | 0.045 parts (0.19 | Benzimidazole | 0.045 parts (0.38 | DMF/water | Cu | 5 | 100 | 1:600 |
| | | molar equivalents) | | molar equivalents) | 90 parts | | | | |
| Ex. 52 | Cu(NO₃)₂•3H₂O | 0.045 parts (0.19 | Benzimidazole | 0.045 parts (0.38 | DMF/water | Cu | 5 | 500 | 1:600 |
| | | molar equivalents) | | molar equivalents) | 90 parts | | | | |
| Ex. 53 | Cu(NO₃)₂•3H₂O | 0.045 parts (0.19 | Benzimidazole | 0.045 parts (0.38 | DMF/water | Cu | 5 | 1,500 | 1:600 |
| | | molar equivalents) | | molar equivalents) | 90 parts | | | | |
| Comp. | None | — | Benzimidazole | 0.38 molar | DMF/water | Cu | 5 | 200 | 1:600 |
| Ex 1 | | | | equivalents | 90 parts | | | | |
| Comp | None | — | Thioisocyanuric | 0.38 molar | Water | Cu | 5 | 200 | 1:600 |
| Ex. 2 | | | acid | equivalents | (pH 3.7) | | | | |

| | | | | | |
|---|---|---|---|---|---|
| Comp | Plating | Cu | 5 | 200 | 1:600 |
| Ex. 3 | | | | | |
| Comp. | Copper oxide (normal blackening treatment) | Cu | 5 | 200 | 1:600 |
| Ex. 4 | | | | | |

TABLE 4

| | MOF evaluation | | | Evaluation result | |
|---|---|---|---|---|---|
| | MOF | | | Amount of | |
| | layer | | Average | line width | Visibility |
| | thickness | Coverage | particle size | reduction | suppression |
| Ex. 1 | 4 | 4 | 4 | 5 | 4 |
| Ex. 2 | 3 | 3 | 3 | 4 | 3 |
| Ex. 3 | 3 | 3 | 3 | 4 | 3 |
| Ex. 4 | 3 | 3 | 3 | 4 | 3 |
| Ex. 5 | 3 | 3 | 3 | 4 | 3 |
| Ex. 6 | 4 | 4 | 4 | 5 | 4 |
| Ex. 7 | 3 | 3 | 3 | 4 | 3 |
| Ex. 8 | 3 | 3 | 3 | 4 | 3 |
| Ex. 9 | 4 | 4 | 4 | 5 | 4 |
| Ex. 10 | 4 | 4 | 4 | 5 | 4 |
| Ex. 11 | 3 | 3 | 3 | 4 | 3 |
| Ex. 12 | 3 | 3 | 3 | 4 | 3 |
| Ex. 13 | 3 | 3 | 3 | 4 | 3 |
| Ex. 14 | 4 | 4 | 4 | 5 | 4 |
| Ex. 15 | 3 | 4 | 4 | 3 | 3 |
| Ex. 16 | 4 | 4 | 4 | 5 | 4 |
| Ex. 17 | 4 | 4 | 4 | 5 | 4 |
| Ex. 18 | 4 | 4 | 4 | 5 | 4 |
| Ex. 19 | 4 | 4 | 4 | 4 | 4 |
| Ex. 20 | 4 | 4 | 4 | 4 | 4 |
| Ex. 21 | 4 | 4 | 4 | 4 | 4 |
| Ex. 22 | 4 | 4 | 4 | 5 | 4 |
| Ex. 23 | 3 | 4 | 4 | 4 | 3 |

TABLE 5

| | MOF evaluation | | | Evaluation result | |
|---|---|---|---|---|---|
| | MOF | | | Amount of | |
| | layer | | Average | line width | Visibility |
| | thickness | Coverage | particle size | reduction | suppression |
| Ex. 24 | 4 | 5 | 5 | 5 | 4 |
| Ex. 25 | 4 | 5 | 5 | 5 | 4 |
| Ex. 26 | 4 | 5 | 5 | 5 | 4 |
| Ex. 27 | 3 | 4 | 4 | 5 | 4 |
| Ex. 28 | 4 | 5 | 5 | 5 | 5 |
| Ex. 29 | 4 | 5 | 5 | 5 | 5 |
| Ex. 30 | 4 | 5 | 5 | 5 | 5 |
| Ex. 31 | 4 | 5 | 5 | 5 | 5 |
| Ex. 32 | 4 | 5 | 5 | 5 | 5 |
| Ex. 33 | 4 | 5 | 5 | 5 | 5 |
| Ex. 34 | 4 | 5 | 5 | 5 | 5 |
| Ex. 35 | 4 | 5 | 5 | 5 | 5 |
| Ex. 36 | 4 | 5 | 5 | 5 | 5 |
| Ex. 37 | 4 | 4 | 4 | 5 | 4 |
| Ex. 38 | 4 | 4 | 4 | 5 | 4 |
| Ex. 39 | 4 | 4 | 4 | 5 | 4 |

TABLE 6

| | MOF evaluation | | | Evaluation result | |
|---|---|---|---|---|---|
| | MOF | | | Amount of | |
| | layer | | Average | line width | Visibility |
| | thickness | Coverage | particle size | reduction | suppression |
| Ex. 40 | 4 | 4 | 4 | 4 | 4 |
| Ex. 41 | 4 | 4 | 4 | 4 | 4 |
| Ex. 42 | 4 | 4 | 4 | 5 | 4 |
| Ex. 43 | 4 | 4 | 4 | 5 | 4 |
| Ex. 44 | 3 | 4 | 4 | 5 | 5 |
| Ex. 45 | 4 | 4 | 4 | 5 | 5 |
| Ex. 46 | 4 | 4 | 4 | 5 | 4 |
| Ex. 47 | 5 | 4 | 4 | 5 | 3 |
| Ex. 48 | 3 | 4 | 4 | 5 | 5 |
| Ex. 49 | 4 | 4 | 4 | 5 | 4 |
| Ex. 50 | 4 | 4 | 4 | 5 | 4 |
| Ex. 51 | 4 | 4 | 4 | 5 | 4 |
| Ex. 52 | 4 | 4 | 4 | 5 | 4 |
| Ex. 53 | 4 | 4 | 4 | 5 | 4 |
| Comp. | 2 | 1 | 1 | 2 | 2 |
| Ex. 1 | | | | | |
| Comp. | 1 | 1 | 1 | 1 | 1 |
| Ex. 2 | | | | | |
| Comp. | 1 | 5 | 1 | 2 | 4 |
| Ex. 3 | | | | | |
| Comp. | 1 | 5 | 1 | 2 | 4 |
| Ex. 4 | | | | | |

Details of the abbreviations and manufacturers for the various types of compounds in Table 1 to Table 3 are as follows.

Cu(NO₃)₂.3H₂O: Wako Pure Chemical Industries, Ltd.
Fe(NO₃)₃: Wako Pure Chemical Industries, Ltd.
Co(NO₃)₂.6H₂O: Wako Pure Chemical Industries, Ltd.
Ni(NO₃)₂.6H₂O: Wako Pure Chemical Industries, Ltd.
Al(NO₃)₃.9H₂O: Wako Pure Chemical Industries, Ltd.
Zn(NO₃)₂: Wako Pure Chemical Industries, Ltd.

### AgNO₃: Wako Pure Chemical Industries, Ltd.

### ZrCl₄: Wako Pure Chemical Industries, Ltd.

### CuBr: Wako Pure Chemical Industries, Ltd.

### Cul: Wako Pure Chemical Industries, Ltd.

### CuCl₂: Wako Pure Chemical Industries, Ltd.

### Cu(OH)₂: Wako Pure Chemical Industries, Ltd.

Cu(C₆H₄O₇).2.5H₂O: copper (II) citrate 2.5 hydrate, Wako Pure Chemical Industries, Ltd.
Pyridine-4-carboxylic acid: Wako Pure Chemical Industries, Ltd.
2,3-Pyrazinedicarboxylic acid: Wako Pure Chemical Industries, Ltd.

### Benzimidazole: Tokyo Chemical Industry Co., Ltd.

### 2-Methylimidazole: Tokyo Chemical Industry Co., Ltd.

### Mercaptoimidazole: Tokyo Chemical Industry Co., Ltd.

### Triazine: Tokyo Chemical Industry Co., Ltd.

DABCO: 1,4-diazabicyclo[2.2.2]octane, Tokyo Chemical Industry Co., Ltd.

### 4,4′-Bipyridine: Tokyo Chemical Industry Co., Ltd.

### Pyrimidine: Tokyo Chemical Industry Co., Ltd.

Trimesic acid: 1,3,5-benzenetricarboxylic acid, Tokyo Chemical Industry Co., Ltd.
cis-1,2-Cyclohexanedicarboxylic acid: Tokyo Chemical Industry Co., Ltd.
PEI: polyethyleneimine, Aldrich, branched polyethyleneimine, Mw 25,000, Mn10,000
PVP: polyvinylpyrrolidone, Aldrich, polyvinylpyrrolidone, Mw 360,000 1-Methylimidazole: Tokyo Chemical Industry Co., Ltd.
Cetyltrimethylammonium bromide: (C₁₆H₃₃)N(CH₃)₃Br, cetyltrimethylammonium bromide, Tokyo Chemical Industry Co., Ltd.
n-Butylamine: n-butylamine, Tokyo Chemical Industry Co., Ltd.
Dodecanoic acid: dodecanoic acid, Tokyo Chemical Industry Co., Ltd.
Aluminum: aluminum
TAT: titanium/aluminum/titanium layered body
MAM: molybdenum/aluminum/molybdenum layered body

With regard to the metal wiring, a uniform metal film having predetermined wiring film thickness was formed by a sputtering method, and the metal wiring was formed by a method employing the resist.

### <Production of Touch Panel>

In the same manner as in Example 1, a polyethylene terephthalate (PET) substrate (100 mm×100 mm) having a 200 nm thick copper film formed thereon was subjected to coating with the resist composition, exposure, development and patterning of a resist layer. Patterning of the resist layer was carried out so as to give a pattern corresponding to a mesh-shaped touch sensor part, a 0.02 mm to 0.05 mm wide wiring part for lead-out, and a connector.

Subsequently, after etching with a copper etchant (CleanEtch SE-07, Ryoko Chemical Co., Ltd., 7 times diluted product) was carried out, the resist was removed, thus producing a substrate comprising the copper wiring layer. This wiring layer had a touch sensor part corresponding to a copper wiring pattern with a line width of 5 μm, a wiring film thickness of 200 nm, and a wiring pitch of 1:600, and had pattern parts corresponding to wiring parts for lead-out and a connector.

A first touch panel member was formed by carrying out the MOF processing. Furthermore, a second touch panel member was formed in the same manner as above, and the first and second touch panel members were laminated. The pattern parts, corresponding to the connector, of the first and second touch panel members were connected to a drive IC (integrated circuit) by means of a flexible printed circuit (FPC), thus producing a touch panel.

The change in capacitance generated at the time of an operation of touching the touch panel was measured, and presence or absence of a touching operation was confirmed. Also, a test was carried out with regard to whether or not the position of touching could be detected when a touching operation was carried out.

It was confirmed that there were no problems in the operation of the touch panel.

What is claimed is:

1. A touch panel member comprising:
a support,
metal wiring above at least one face of the support, and
a layer comprising a metal-organic framework on at least part of the surface of the metal wiring,
wherein the layer comprising the metal-organic framework has an average thickness of 10 to 5,000 nm.

2. The touch panel member according to claim 1, wherein the layer comprising the metal-organic framework has an average coverage of 80% to 100% with respect to an upper face and side face of the metal wiring in a touch sensor part.

3. The touch panel member according to claim 1, wherein the metal wiring has an average thickness of 50 to 3,000 nm.

4. The touch panel member according to claim 1, wherein the metal wiring has a line width of 1 to 10 μm, and the metal wiring has an interwiring distance of 100 to 10,000 μm.

5. The touch panel member according to claim 1, wherein the metal-organic framework is a structure comprising a metal ion and a compound comprising at least two coordinating groups that coordinate to the metal ion, and
the metal ion is an ion of at least one type of metal selected from the group consisting of copper, zinc, cadmium, silver, cobalt, nickel, iron, ruthenium, aluminum, chromium, molybdenum, manganese, palladium, rhodium, and magnesium.

6. The touch panel member according to claim 5, wherein the compound comprising at least two coordinating groups is a compound selected from the group consisting of a compound that comprises a ring comprising a coordinating nitrogen atom within the ring and that comprises at least two coordinating nitrogen atoms, a compound that comprises one each of a carboxyl group and a ring comprising a coordinating nitrogen atom within the ring, and a compound comprising at least two carboxyl groups.

7. The touch panel member according to claim 6, wherein the ring comprising a coordinating nitrogen atom within the ring is an aromatic ring selected from the group consisting of an imidazole ring, a triazole ring, a pyridine ring, and a pyrimidine ring.

8. The touch panel member according to claim 1, wherein the metal-organic framework comprises a crystal size adjusting agent.

9. The touch panel member according to claim 8, wherein the crystal size adjusting agent is at least one type of compound selected from the group consisting of polyethyleneimine, polyvinylpyrrolidone, a 1-alkylimidazole, a tetraalkylammonium halide, a monoalkylamine, and an aliphatic carboxylic acid.

10. The touch panel member according to claim 1, wherein the metal wiring is metal wiring comprising at least one type of metal selected from the group consisting of copper, aluminum, titanium, molybdenum, silver, chromium, nickel, and zinc.

11. A touch panel comprising the touch panel member according to claim 1.

12. A touch panel display device comprising the touch panel member according to claim 1.

13. A process for producing a touch panel member, comprising:
a step of forming metal wiring above a support, and
a step of forming a layer that has an average thickness of 10 to 5,000 nm and comprises a metal-organic framework on the surface of the metal wiring using a composition that comprises a solvent, a compound comprising at least two coordinating groups, and at least one type of compound selected from the group consisting of a metal hydroxide and a metal salt of an inorganic acid or organic acid.

14. The process for producing a touch panel member according to claim 13, wherein the composition comprises metal-organic framework particles, and the metal-organic framework particles have an average particle size of 1 to 1,000 nm.

15. The process for producing a touch panel member according to claim 13, wherein the compound comprising at least two coordinating groups comprises a compound selected from the group consisting of a compound that comprises a ring comprising a coordinating nitrogen atom within the ring and that comprises at least two coordinating nitrogen atoms, a compound that comprises one each of a carboxyl group and a ring comprising a coordinating nitrogen atom within the ring, and a compound comprising at least two carboxyl groups.

16. The process for producing a touch panel member according to claim 13, wherein the composition further comprises a crystal size adjusting agent.

17. The process for producing a touch panel member according to claim 16, wherein the crystal size adjusting agent is at least one type of compound selected from the group consisting of polyethyleneimine, polyvinylpyrrolidone, a 1-alkylimidazole, a tetraalkylammonium halide, a monoalkylamine, and an aliphatic carboxylic acid.
